(19) United States
(12) Patent Application Publication
(10) Pub. No.: US 2006/0049470 A1
(43) Pub. Date: Mar. 9, 2006

(54) Double layer polysilicon gate electrode

(76) Inventors: Chia-Lin Chen, Hsinchu (TW); Ming-Jie Huang, Hsinchu city (TW); Chien-Hao Chen, Chuangwei township (TW); Tze-Liang Lee, Hsinchu (TW); Shih-Chang Chen, Hsinchu (TW)

Correspondence Address: TUNG & ASSOCIATES;Randy W. Tung, Suite 120, 838 West Long Lake Rd, Bloomfield Hills, MI, 48302, US

(21) Appl. No.: 10/936,271

(22) Filed: Sep. 7, 2004

(51) Int. Cl. H01L 29/76

(52) U.S. Cl. 257/408

(57) ABSTRACT

A method for forming a microelectronic product and the microelectronic product resulting from the method both employ a bilayer gate electrode. The bilayer gate electrode employs: (1) a first layer formed of a random oriented polycrystalline silicon material; and (2) a second layer laminated to the first layer and formed of a columnar oriented polycrystalline silicon material. The gate electrode provides enhanced performance to a semiconductor device within which it is formed.

### BACKGROUND OF THE INVENTION

1. Field of the Invention

The invention relates generally to gate electrodes within microelectronic products. More particularly, the invention relates to gate electrodes with enhanced performance within microelectronic products.

2. Description of the Related Art

Semiconductor products are formed from semiconductor substrates within which are formed electronic devices and over which are formed patterned conductor layers that are separated by dielectric layers. Semiconductor products typically employ field effect devices as electronic devices. In turn field effect devices typically employ a gate electrode as a control element to control an electric field within a channel region of a semiconductor substrate such that current flow may be modulated through the channel region.

While field effect devices are thus common in the semiconductor product fabrication art, they are nonetheless not entirely without problems. As semiconductor product integration levels increase and semiconductor device dimensions decrease, it is often difficult to form semiconductor devices with enhanced performance.

It is thus desirable to form semiconductor devices with enhanced performance. It is towards the foregoing object that the present invention is directed.

Various semiconductor products and devices having desirable properties, and methods for fabrication thereof, have been disclosed within the semiconductor product fabrication art.

Included but not limiting among the products, devices and methods are those disclosed within: (1) Gardner et al., in U.S. Pat. No. 5,888,853 (a semiconductor product having multi-level transistor devices formed therein and method for fabrication thereof); (2) Matsuda, in U.S. Pat. No. 6,037,245 (a dual layer gate electrode for use within a semiconductor device and a method for fabrication thereof); and (3) Wang et al., in U.S. Pat. No. 6,534,414 (a dual mask method for forming a dual gate electrode within a semiconductor product).

Desirable are additional semiconductor products and devices having enhanced performance, and methods for fabrication thereof.

### SUMMARY OF THE INVENTION

A first object of the invention is to provide a semiconductor device and a method for fabrication thereof.

A second object of the invention is to provide a semiconductor device and a method for fabrication thereof in accord with the first object of the invention, wherein the semiconductor device is fabricated with enhanced performance.

In accord with the objects of the invention, the invention provides a gate electrode for use within a semiconductor device. The gate electrode comprises: (1) a first layer formed of a random oriented polycrystalline silicon material; and (2) a second layer laminated to the first layer and formed of a columnar oriented polycrystalline silicon material.

The invention provides a semiconductor device fabricated with enhanced performance, and a method for fabrication thereof.

The invention realizes the foregoing object within the context of a gate electrode for use within a semiconductor device. The gate electrode comprises (1) a first layer formed of a random oriented polycrystalline silicon material; and (2) a second layer laminated to the first layer and formed of a columnar oriented polycrystalline silicon material. Within the gate electrode: (1) the first layer provides for: (a) enhanced device performance; and (b) enhanced etching uniformity; and (2) the second layer provides for enhanced sheet resistance uniformity when forming a silicide layer thereupon.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4, FIG. 5 and FIG. 6 show a series of schematic cross-sectional diagrams illustrating the results of progressive stages of fabricating a semiconductor product in accord with a preferred embodiment of the invention.

FIG. 6 shows a diagram of Off Current versus Saturation Current for a series of field effect transistor devices having formed therein a series of gate electrodes in accord with the invention and not in accord with the invention.

FIG. 7 shows a diagram of Cumulative Percent versus Sheet Resistance for a series of silicided polysilicon layers formed in accord with the invention and not in accord with the invention.

### DESCRIPTION OF THE PREFERRED EMBODIMENT

The invention provides a semiconductor product fabricated with enhanced performance, and a method for fabrication thereof.

The invention realizes the foregoing object within the context of a gate electrode for use within a semiconductor device. The gate electrode comprises (1) a first layer formed of a random oriented polycrystalline silicon material; and (2) a second layer laminated to the first layer and formed of a columnar oriented polycrystalline silicon material. Within the gate electrode: (1) the first layer provides for: (a) enhanced device performance; and (b) enhanced etching uniformity; and (2) the second layer provides for enhanced sheet resistance uniformity when forming a silicide layer thereupon.

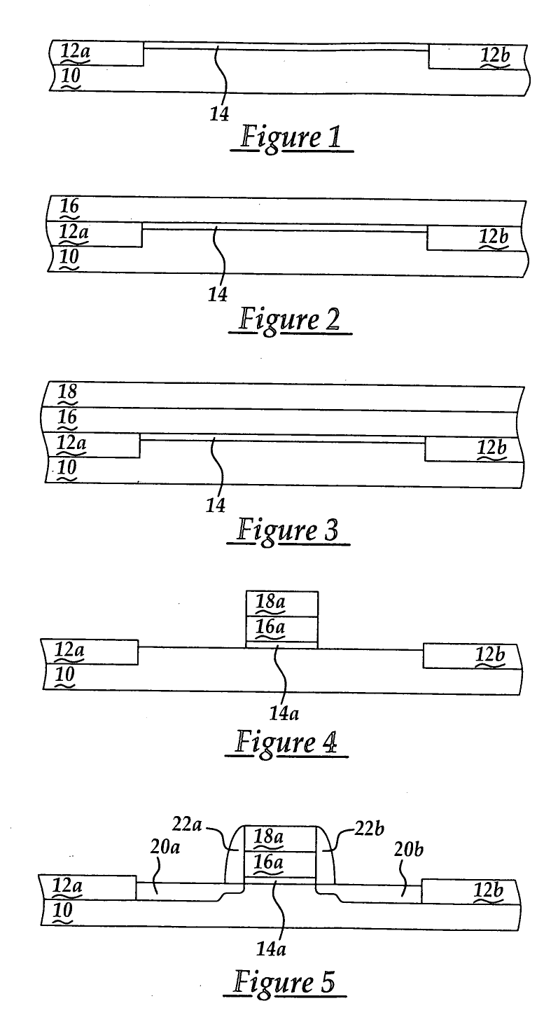

FIG. 1 to FIG. 6 show a series of schematic cross-sectional diagrams illustrating the results of progressive stages in fabricating a semiconductor product in accord with a preferred embodiment of the invention.

FIG. 1 shows a semiconductor substrate 10 having formed therein a pair of isolation regions 12a and 12b which define an active region of the semiconductor substrate 10. FIG. 1 also illustrates a gate dielectric layer 14 formed upon the active region of the semiconductor substrate 10.

The semiconductor substrate 10 may be a bulk semiconductor substrate or a silicon on insulator semiconductor substrate. It may be formed employing semiconductor materials selected from the group including but not limited to silicon semiconductor materials, germanium semiconductor materials and silicon-germanium alloy semiconductor materials.

The pair of isolation regions 12a and 12b may be formed employing methods and materials as are conventional in the semiconductor product fabrication art. The pair of isolation regions 12a and 12b may be formed as isolation regions including but not limited to shallow trench isolation regions and local oxidation of silicon isolation regions.

The gate dielectric layer 14 may also be formed employing methods and materials as are conventional in the semiconductor product fabrication art. The gate dielectric layer 14 may be formed of a silicon oxide material formed employing a thermal oxidation method or a deposition method. Typically, the gate dielectric layer 14 is formed to a thickness of from about 20 to about 100 angstroms.

FIG. 2 shows the results of forming a first polysilicon layer 16 upon the semiconductor product of FIG. 1. The first polysilicon layer 16 formed upon the pair of isolation regions 12a and 12b and the gate dielectric layer 14.

The first polysilicon layer 16 is formed of a random oriented polycrystalline silicon material formed employing a low pressure chemical vapor deposition method employing a silane silicon source material and a hydrogen carrier gas. The low pressure chemical vapor deposition method also employs: (1) a reactor chamber pressure of from about 1 to about 5 torr; (2) a substrate temperature of from about 580 to about 650 degrees centigrade; (3) a silane flow rate of from about 5 to about 20 standard cubic centimeters per minute; and (4) a hydrogen carrier gas flow rate of from about 100 to about 1000 standard cubic centimeters per minute.

The blanket first polysilicon layer 16 when formed of the random oriented polycrystalline silicon material is subject to a more uniform etching in comparison with etching of a non-random oriented polycrystalline silicon material. Thus, when the first polysilicon layer 16 is subsequently etched, the pair of isolation regions 12a and 12b and the gate dielectric layer 14 are less susceptible to over-etching and pitting. The blanket first polysilicon layer 16 when formed of the random oriented polycrystalline silicon material also provides for enhanced performance of a semiconductor devices ultimately formed in part therefrom. Typically, the blanket first polysilicon layer 16 is formed to a thickness of from about 300 to about 1000 angstroms.

FIG. 3 shows a blanket second polysilicon layer 18 formed upon the blanket first polysilicon layer 16.

The blanket second polysilicon layer 18 is formed of a columnar oriented polycrystalline silicon material. The columnar oriented polycrystalline silicon material is formed employing generally the same low pressure chemical vapor deposition method as employed for forming the random oriented polycrystalline silicon material from which is formed the blanket first polysilicon layer 16, but with a change of carrier gas from hydrogen to nitrogen at the same flow rate. Typically, the blanket second polysilicon layer 18 is formed to a thickness of from about 500 to about 1000 angstroms.

FIG. 4 shows the results of pattering the blanket second polysilicon layer 18, the blanket first polysilicon layer 16 and the gate dielectric layer 14 to form a patterned second polysilicon layer 18a aligned upon a patterned first polysilicon layer 16a in turn aligned upon a patterned gate dielectric layer 14a. The patterned second polysilicon layer 18a and the patterned first polysilicon layer 16a form in an aggregate a gate electrode for use within a field effect transistor device. The patterning may be effected employing photolithographic and etch methods as are conventional in the semiconductor product fabrication art.

FIG. 5 shows a pair of spacer layers 22a and 22b formed adjoining a pair of opposite edges of the gate electrode and the patterned gate dielectric layer 14a. FIG. 5 also shows a pair of source/drain regions 20a and 20b formed into the semiconductor substrate 10 and separated by the gate electrode. The pair of spacer layers 22a and 22b and the pair of source/drain regions 20a and 20b may be formed employing methods and materials as are conventional in the semiconductor product fabrication art.

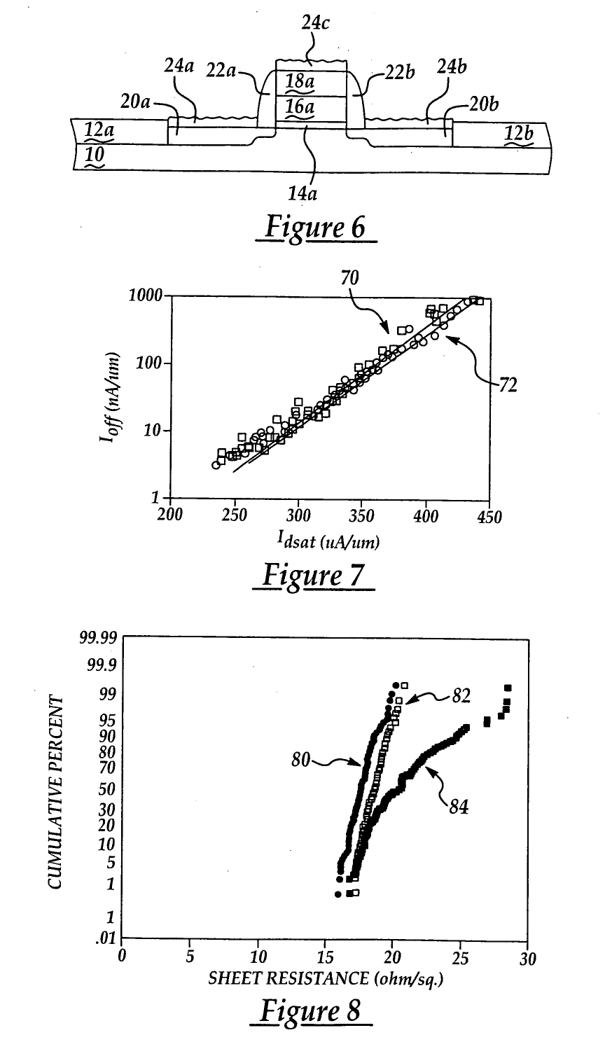

FIG. 6 shows a series of silicide layers 24a, 24b and 24c formed upon surfaces of the pair of source/drain regions 20a and 20b and the patterned second polysilicon layer 18a. The series of silicide layers 24a, 24b and 24c may be formed employing methods as are conventional in the semiconductor product fabrication art. Typically, the series of silicide layers is formed of a nickel or cobalt silicide material formed to a thickness of from about 100 to about 1000 angstroms, while employing a salicide self-aligned method.

FIG. 6 shows a schematic diagram of a semiconductor product having formed therein a field effect transistor device in accord with the invention. The field effect transistor device has formed therein a gate electrode with enhanced performance. The gate electrode is formed as a dual layer polysilicon gate electrode. A first layer within the dual layer gate electrode is formed of a random oriented polycrystalline silicon material and a second layer within the gate electrode is formed of a columnar oriented polycrystalline silicon material.

### EXAMPLES

FIG. 7 shows a graph of Off Current versus Saturation Current for a series of field effect transistor devices having formed therein gate electrodes fabricated in accord with the invention and not in accord with the invention. Reference numeral 70 corresponds to data points for a series of field effect transistor devices formed with gate electrodes formed of a polysilicon material formed employing a furnace deposition method (i.e., a pyrolysis of silane). Reference numeral 72 corresponds with data points for a series of field effect transistor devices formed with gate electrodes formed of a random oriented polycrystalline silicon material formed in accord with the invention (i.e., employing a low pressure chemical vapor deposition method employing silane as a silicon source material and a hydrogen carrier gas). As is illustrated in FIG. 7, transistors formed of gate electrodes formed in accord with the invention have a generally lower off current as a function of saturation current as is desirable in the semiconductor product fabrication art.

FIG. 8 shows a graph of Cumulative Percent versus Sheet Resistance for a series of polysilicon material layers having formed thereupon a series of nickel silicide layers. Reference numeral 80 corresponds with nickel silicide layers formed upon a columnar oriented polycrystalline silicon layer in accord with the invention. Reference numeral 82 corresponds with nickel silicide layers formed upon a furnace depsited polysilicon layer. Reference numeral 84 corresponds with nickel silicide layer formed upon a random oriented polycrystalline silicon layer. As is illustrated in FIG. 8, nickel silicide layers formed upon a columnar oriented polysilicon material have generally lower sheet resistances as are desirable in the semiconductor product fabrication art.

The preferred embodiment and examples of the invention are illustrative of the invention rather than limiting of the invention. Revisions and modifications may be made to methods, materials, structures and dimensions in accord with the preferred embodiment and examples while still providing an embodiment in accord with the invention, further in accord with the accompanying claims.

1. A microelectronic product comprising:
a substrate having formed thereover a polysilicon structure, the polysilicon structure comprising:
a first layer formed of a random oriented polycrystalline silicon material; and
a second layer laminated to the first layer and formed of a columnar oriented polycrystalline silicon material.

2. The product of claim 1 wherein the substrate is a bulk semiconductor substrate.

3. The product of claim 1 wherein the substrate is a silicon on insulator substrate.

4. The product of claim 1 wherein the first layer is formed to a thickness of from about 500 to about 1000 angstroms.

5. The product of claim 1 wherein the second layer is formed to a thickness of from about 300 to about 1000 angstroms.

6. A field effect transistor comprising:
a semiconductor substrate;
a gate electrode formed over the semiconductor substrate, the gate electrode comprising:
a first layer formed of a random oriented polycrystalline silicon material; and
a second layer laminated to the first layer and formed of a columnar oriented polycrystalline silicon material; and
a pair of source/drain regions formed into the semiconductor substrate and separated by the gate electrode.

7. The transistor of claim 6 wherein the semiconductor substrate is a bulk semiconductor substrate.

8. The transistor of claim 6 wherein the semiconductor substrate is a silicon on insulator substrate.

9. The transistor of claim 6 wherein the first layer is formed to a thickness of from about 500 to about 1000 angstroms.

10. The transistor of claim 6 wherein the second layer is formed to a thickness of from about 300 to about 1000 angstroms.

11. A method for forming a semiconductor product comprising:
providing a substrate;
forming over the substrate a polysilicon structure comprising:
a first layer formed of a random oriented polycrystalline silicon material; and
a second layer laminated to the first layer and formed of a columnar oriented polycrystalline silicon material.

12. The method of claim 10 wherein the substrate is a bulk semiconductor substrate.

13. The method of claim 10 wherein the substrate is a silicon on insulator substrate.

14. The method of claim 10 wherein the first layer is formed to a thickness of from about 500 to about 1000 angstroms.

15. The method of claim 10 wherein the second layer is formed to a thickness of from about 300 to about 1000 angstroms.

16. The method of claim 10 wherein the first layer is formed employing a chemical vapor deposition method employing a hydrogen carrier gas.

17. The method of claim 10 wherein the second layer is formed employing a chemical vapor deposition method employing a nitrogen carrier gas.

18. The method of claim 10 wherein the polysilicon structure is a gate electrode within a field effect transistor.

19. The method of claim 10 wherein the field effect transistor is an N channel field effect transistor.

20. The method of claim 10 wherein the field effect transistor is a P channel field effect transistor.
